(19) United States
(12) Patent Application Publication
(10) Pub. No.: US 2012/0033382 A1
(43) Pub. Date: Feb. 9, 2012

(54) HEAT SINK, LIQUID COOLING UNIT, AND ELECTRONIC APPARATUS

(75) Inventors: Yosuke Tsunoda, Kawasaki (JP); Masumi Suzuki, Kawasaki (JP); Michimasa Aoki, Kawasaki (JP); Masaru Sugie, Kawasaki (JP); Shinichirou Kouno, Kawasaki (JP); Hiroshi Muto, Sagamihara (JP); Kenji Katsumata, Kawasaki (JP)

(73) Assignee: FUJITSU LIMITED, Kawasaki-shi (JP)

(21) Appl. No.: 13/167,230

(22) Filed: Jun. 23, 2011

(30) Foreign Application Priority Data
Aug. 5, 2010 (JP) 2010-176132

(51) Int. Cl. H05K 7/20; F28D 15/00; F28F 7/00

(52) U.S. Cl. 361/699; 165/185; 165/104.31

(57) ABSTRACT

A heat sink for absorbing heat which is generated by an electronic module by using a coolant which flows in its internal portion, comprises a housing which is provided with, in its internal portion, a first surface which is located in the vicinity of the electronic module and a second surface which faces the first surface and comprises fins which extend from the first surface toward the second surface, wherein a projecting portion projecting from the second surface toward the first surface is formed at the second surface, between the top edges of the fins on the second surface side and the second surface.

### CROSS REFERENCE TO RELATED APPLICATION

This application claims priority of Japan Patent Application Number 2010-176132, filed on Aug. 5, 2010.

### FIELD

The present invention relates to a heat sink for absorbing heat which is generated by an electronic module and a liquid cooling unit and an electronic apparatus which are provided with a heat sink.

### BACKGROUND

Notebook personal computers and other electronic apparatuses have printed circuit boards installed therein. On the printed circuit boards, for example, LSI chips and other electronic modules are mounted. In order to absorb heat which is generated by these electronic modules, a liquid cooling unit provided with a heat sink is disposed on the printed circuit board.

As related art, Japanese Laid-Open Patent Publication No. 2002-261480 is known.

When using fins to raise a cooling efficiency of a heat sink, the heat which is propagated to the fins is absorbed by a coolant which flows along the wall surfaces of the fins. However, due to frictional resistance which occurs between the wall surfaces of the fins and the coolant, the flow velocity of the coolant which flows along the wall surfaces of the fins falls. Contrary to this, coolant which flows over a position away from the wall surfaces of the fins, to a certain extent, is not influenced much at all, by the frictional resistance which occurs between the wall surfaces of the fins and the coolant. For this reason, the flow velocity of the coolant which flows over a position away from the wall surfaces of the fins, to a certain extent, becomes faster than the flow velocity of the coolant which flows along the wall surfaces of the fins.

In this way, inside a heat sink provided with fins, a plurality of flows of coolant having different flow velocities are formed, therefore the cooling efficiency of the heat sink cannot be sufficiently raised.

### SUMMARY

Accordingly, it is an object of the embodiment to provide a heat sink which improves the cooling efficiency over that of the related art.

According to a first aspect of the invention, there is provided a heat sink for absorbing heat which is generated by an electronic module by using a coolant which flows through its internal portion, comprising a housing which is provided with, in its internal portion, a first surface which is located in the vicinity of the electronic module and a second surface which faces the first surface and comprising fins which extend from the first surface toward the second surface, wherein a projecting portion which projects from the second surface toward the first surface is formed at the second surface between the top edges of the fins on the second surface side and the second surface. Further, according to a second aspect of the invention, there is provided a liquid cooling unit which is provided with the above heat sink. Further, according to a third aspect of the invention, there is provided an electronic apparatus which is provided with the above heat sink.

### BRIEF DESCRIPTION OF DRAWINGS

FIG. 1 is a perspective view illustrating an example of a notebook PC of a first embodiment according to the invention.

FIG. 2 is a perspective view illustrating an example of the structure of an internal portion of a housing body of the first embodiment disclosed in the present specification.

FIG. 3 is a plan view illustrating an example of a liquid cooling unit of the first embodiment disclosed in the present specification.

FIG. 4 is a plan view illustrating an example of the structure of the internal portion of a heat sink of the first embodiment disclosed in the present specification.

FIG. 5A is a cross-sectional view taken along a line A-A in FIG. 3, and FIG. 5B is a cross-sectional view taken along a line B-B in FIG. 3.

FIG. 6 is a cross-sectional view taken along a line C-C in FIG. 3.

FIG. 7A is a plan view illustrating an example of the structure of the internal portion of a heat sink of a second embodiment disclosed in the present specification, and FIG. 7B is a cross-sectional view taken along a line D-D in FIG. 7A.

FIG. 8 is a cross-sectional view taken along a line E-E in FIG. 7A.

FIG. 9 is a cross-sectional view illustrating an example of a heat sink of a third embodiment disclosed in the present specification.

FIG. 10 is a plan view illustrating an example of the structure of the internal portion of a heat sink of a fourth embodiment disclosed in the present specification.

FIG. 11 is a cross-sectional view as seen from an arrow F-F direction in FIG. 10.

FIG. 12 is a cross-sectional view illustrating an example of a heat sink of a fifth embodiment.

FIGS. 13A, 13B, and 13C are diagrams illustrating various modifications of a projecting portion.

### DESCRIPTION OF EMBODIMENTS

According to the heat sink of each embodiment, the cooling efficiency can be improved to more than that of the related art.

### (1) First Embodiment

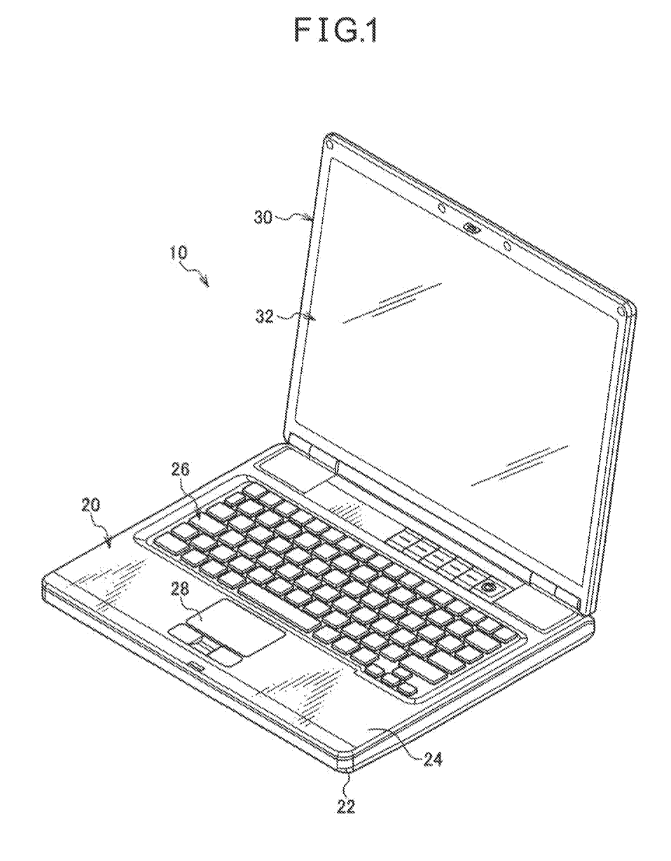

First, with reference to FIG. 1, a notebook personal computer (notebook PC) 10 will be explained as an example of the electronic apparatus according to the first embodiment. FIG. 1 is a perspective view illustrating an example of the notebook PC 10 of the first embodiment. As shown in FIG. 1, the notebook PC 10 is provided with a housing body 20 and a display use housing 30. The display use housing 30 is coupled with the housing body 20 so that opening/closing is possible.

The housing body 20 is provided with a base 22 and a cover 24. The cover 24 can be attached/detached to/from the base 22. Further, on the surface of the cover 24, a keyboard 26, a pointing device 28, and other input devices are disposed. The display use housing 30 is provided with a liquid crystal panel module 32. The liquid crystal panel module 32 displays text, graphics, etc.

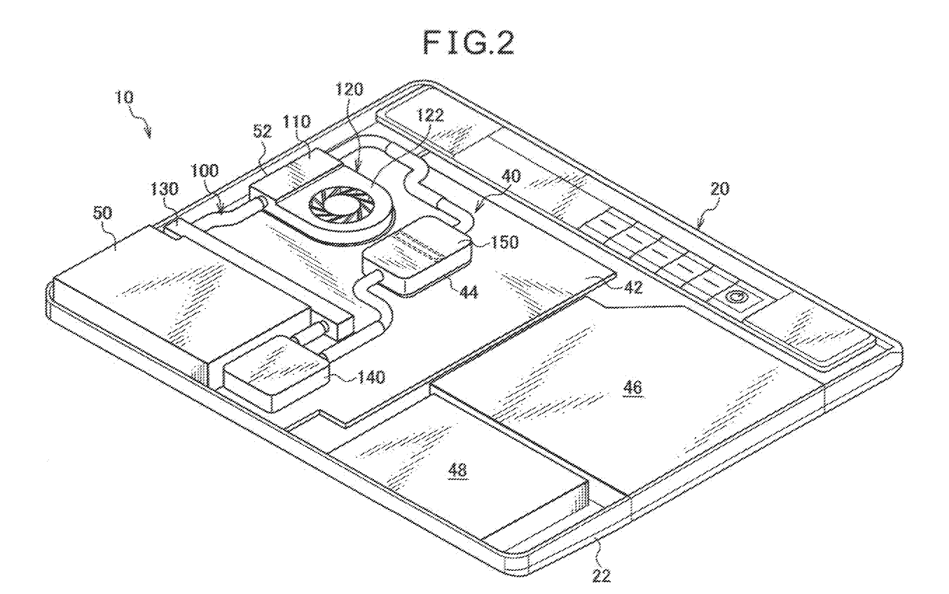

Next, with reference to FIG. 2, the structure of the internal portion of the housing body 20 will be explained. FIG. 2 is a perspective view showing an example of the structure of the internal portion of the housing body 20 of the first embodiment. As shown in FIG. 2, the housing body 20 of the first embodiment is provided with a printed circuit board unit 40, a DVD (digital versatile disk) drive device 46, a hard disk drive device 48, a card unit 50, and a liquid cooling unit 100.

The printed circuit board unit 40 is provided with a printed circuit board 42 and an electronic module 44. The electronic module 44 is mounted on the surface of the printed circuit board 42. The electronic module 44 is for example an LSI circuit (large scale integrated circuit). On the electronic module 44 such as an LSI circuit, for example, a central processing unit chip is mounted. The central processing unit chip executes processing based on the operating system and application software. When the central processing unit chip executes the processing, the electronic module 44 such as an LSI circuit generate heat. In order to absorb the heat generated by the electronic module 44, a liquid cooling unit 100 is attached to the printed circuit board unit 40. The detailed configuration of the liquid cooling unit 100 will be explained later.

The DVD drive device 46 reads data from a DVD and writes data to the DVD. The hard disk drive device 48 stores, for example, the operating system and application software explained above. Further, the card unit 50 is mounted on the printed circuit board 42. Into the card unit 50, for example, a memory card or LAN (Local Area Network) card is inserted.

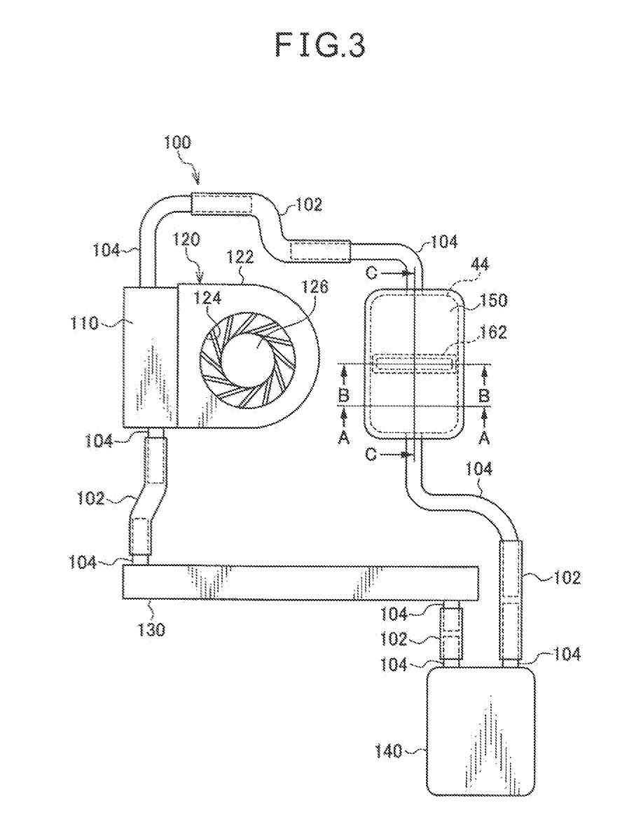

Here, with reference to FIG. 3, the liquid cooling unit 100 of the first embodiment will be explained. FIG. 3 is a plan view showing an example of the liquid cooling unit 100 of the first embodiment. As shown in FIG. 3, the liquid cooling unit 100 of the first embodiment is provided with a heat exchanger 110, fan unit 120, tank 130, pump 140, and heat sink 150. Members configuring the liquid cooling unit 100 are connected by hoses 102 and metal pipes 104 to form a circulation route. By the coolant which flows along the circulation route, the heat generated by the electronic module 44 is discharged to the outside of the notebook PC 10. As the coolant, use is made of, for example, a propylene glycol-based antifreeze.

The heat exchanger 110 takes the heat from the coolant which flows into the heat exchanger 110. The heat exchanger 110 is disposed in the vicinity of an exhaust port 52 (see FIG. 2) formed at the side surface of the housing body 20. Further, a fan unit 120 is disposed in the vicinity of the heat exchanger 110. The fan unit 120 generates an air flow from the heat exchanger 100 toward the exhaust port 52. For this reason, the heat taken from the coolant by the liquid cooling unit 100 is discharged through the exhaust port 52 to the outside of the notebook PC 10.

The fan unit 120 is provided with a fan housing 122 and a fan 126. On the bottom plate and top plate of the fan housing 122, an air intake opening 124 is formed. The internal space of the fan housing 122 and the outside space of the fan housing 122 are connected through the air intake opening 124.

The tank 130 is disposed downstream of the heat exchanger 110. The tank 130 stores the coolant stripped of heat by the heat exchanger 110. The pump 140 is disposed downstream of the tank 130. The pump 140 discharges the coolant stored in the tank 130 to generate the flow of the coolant which flows along the circulation route. The pump 140 is, for example, a piezoelectric pump.

The heat sink 150 is disposed downstream of the pump 140. As shown in FIG. 2, the heat sink 150 is disposed above the electronic module 144 which generates heat. The heat sink 150 absorbs the heat generated by the electronic module 44. The detailed configuration of the heat sink 150 will be explained later. The heat exchanger 110 explained above is located downstream of the heat sink 150. In the liquid cooling unit 100, a circulation route is formed as explained above.

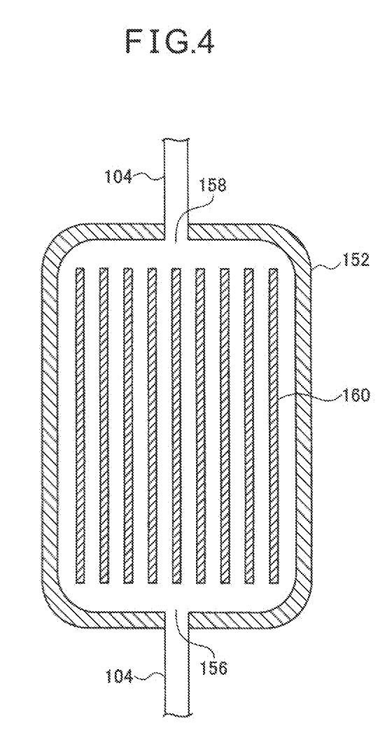

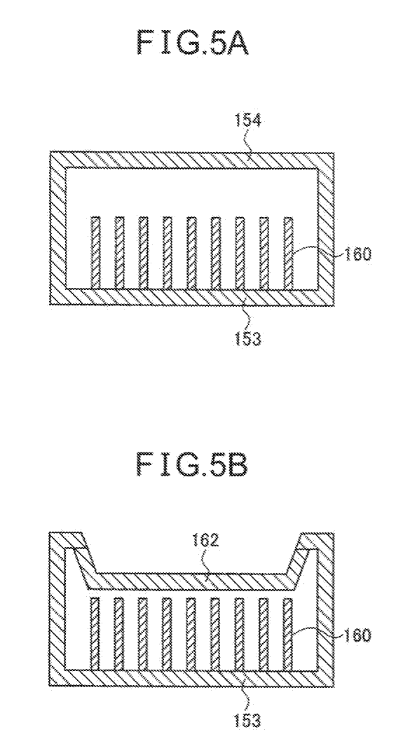

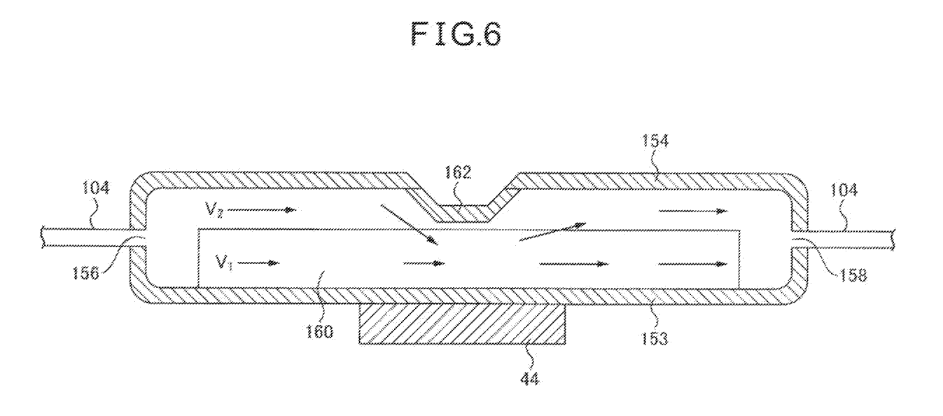

Next, the structure of the heat sink 150 of the first embodiment will be explained in detail with reference to FIG. 4 to FIG. 6. FIG. 4 is a plan view showing an example of the structure of the internal portion of the heat sink 150. Specifically, FIG. 4 is a plan view showing an example of the heat sink 150 when the top surface 154 of the housing 152 (FIG. 6) which will be explained later is removed. FIG. 5A is a cross-sectional view taken along a line A-A in FIG. 3, and FIG. 5B is a cross-sectional view taken along a line B-B in FIG. 3. FIG. 6 is a cross-sectional view taken along a line C-C in FIG. 3.

As shown in FIG. 4, the heat sink 150 is provided with a housing 152 and fins 160. In the example shown in FIG. 4, the heat sink 150 is provided with nine fins 160. Further, in the housing 152, an inflow port 156 and an outflow port 158 are formed. To the inflow port 156 and outflow port 158 are connected to the metal pipes 104. The coolant, which passes through the inflow port 156 and flows into the internal portion of the housing 152, passes through the outflow port 158 and flows out to an external portion of the housing 152.

As shown in FIG. 6, the housing 152 includes a bottom surface (first surface) 153 and a top surface (second surface) 154. The bottom surface 153 contacts the electronic module 44. Further, inside the housing 152, the fins 160 are extended from the bottom surface 153 toward the top surface 154. The fins 160 are formed by a metal material having a high heat conductivity, for example, aluminum. For this reason, the heat generated by the electronic module 44 is propagated to the bottom surface 153 of the housing 152 with fins 160 and is absorbed by the coolant.

Here, as shown in FIG. 5A, the fins 160 of the first embodiment contact the bottom surface 153, but do not contact the top surface 154. For this reason, between the top edges of the fins 160 and the top surface 154 of the housing 152, there is a region where there are no fins 160.

Further, as shown in FIG. 5B and FIG. 6, between the top edges of the fins 160 and the top surface 154 of the housing 152, a projecting portion 162 projecting from the top surface 154 toward the bottom surface 153 is formed at the top surface 154 of the housing 152. The projecting portion 162 is formed by, for example, pushing down the top surface 154 of the housing 152. Note that, in the example shown in FIG. 5B and FIG. 6, the top edges of the fins 160 do not contact the projecting portion 162, but the top edges of the fins 160 may contact the projecting portion 162 as well.

In the heat sink 150 of the first embodiment, since, between the top edges of the fins 160 and the top surface 154 of the housing 152, there is a region where there are no fins 160, a flow velocity v₁ of the coolant which flows among the fins 160 is different from the flow velocity v₂ of the coolant which flows between the top edges of the fins 160 and the top surface 154 of the housing 152. Specifically, the coolant which flows among the fins 160 is influenced by the frictional resistance created between the wall surfaces of the fins 160 and the coolant, so the flow velocity v₁ becomes smaller than the flow velocity v₂.

Further, in the heat sink 150 of the first embodiment, since a projecting portion 162 projecting from the top surface 154 toward the bottom surface 153 is formed at the top surface 154 of the housing 152, the coolant which flows between the top edges of the fins 160 and the top surface 154 of the housing 152 strikes the projecting portion 162 and flows into the spaces among the fins. As a result, on the downstream side from the projecting portion 162, the velocity of the coolant, which flows among the fins 160, rises.

Further, on the upstream side from the projecting portion 162, the temperature of the coolant, which flows between the top edges of the fins 160 and the top surface 154 of the housing 152, is lower than the temperature of the coolant, which flows among the fins 160. For this reason, the coolant, which flows between the top edges of the fins 160 and the top surface 154 of the housing 152, strikes the projecting portion 162 and flows into the spaces among the fins 160, whereby the temperature of the coolant which flows among the fins 160 can be lowered on the downstream side from the projecting portion 162. As explained above, according to the heat sink 150 of the first embodiment, the cooling efficiency can be improved over that of the related art.

### (2) Second Embodiment

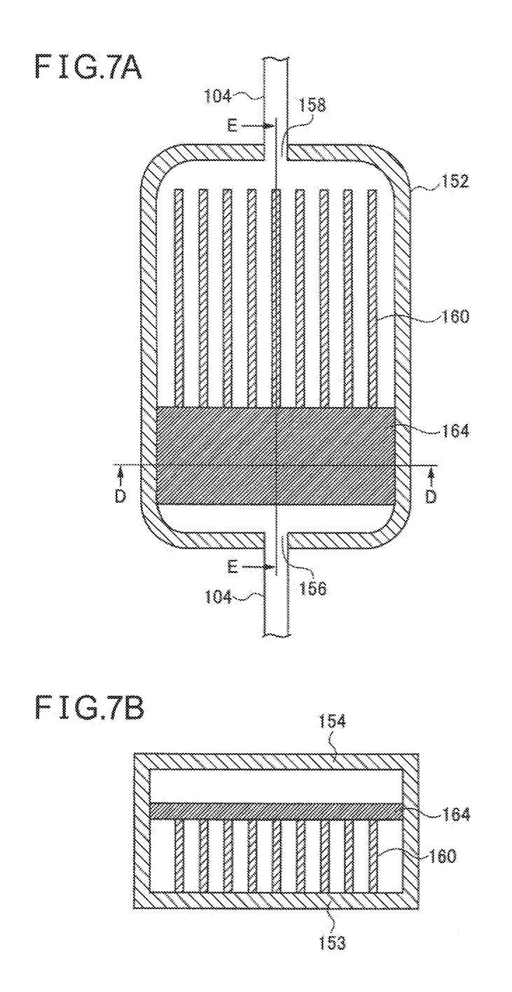

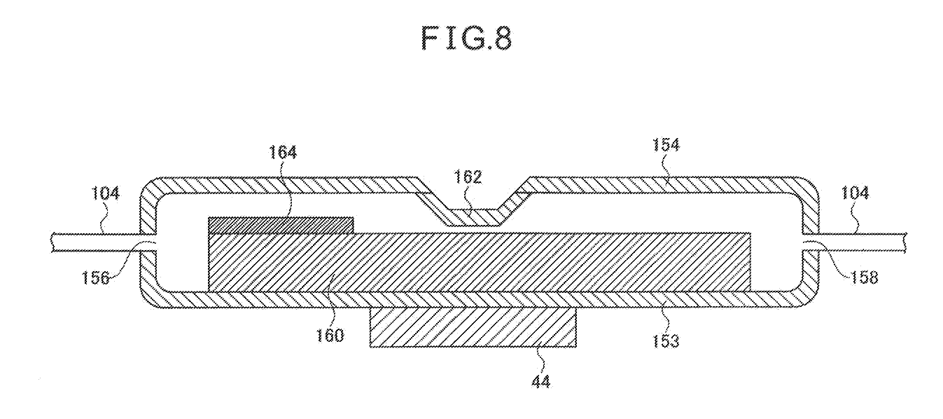

Next, a second embodiment according to the invention will be explained. The second embodiment differs in the configuration of the heat sink 150 from that of the first embodiment explained before. The rest of the configuration is similar to that of the first embodiment, so an explanation will be omitted. Below, the configuration of the heat sink 150 of the second embodiment will be explained with reference to FIGS. 7A and 7B and FIG. 8. FIG. 7A is a plan view showing an example of the heat sink 150 when removing the top surface 154 of the housing 152, and FIG. 7B is a cross-sectional view taken along a line D-D in FIG. 7A. Further, FIG. 8 is a cross-sectional view taken along a line E-E in FIG. 7A.

As shown in FIGS. 7A and 7B and FIG. 8, the heat sink 150 of the second embodiment is different from the first embodiment explained above in the point that a partition plate 164 is provided. The rest of the configuration is similar to that of the first embodiment. As shown in FIGS. 7A and 7B, the partition plate 164 contacts the top edges of the fins 160 and is arranged parallel to the bottom surface 153 of the housing 152. In the same way as the fins 160, the partition plate 164 is formed by a thermally conductive metal material. The partition plate 164 may be formed by the same material as that of the fins 160 or may be formed by a different material.

Further, in the example shown in FIGS. 7A and 7B, the partition plate 164 is arranged so as to contact the top edges of all fins 160. However, it may be arranged so as to contact only the top edges of a portion of the fins 160. Further, in the example shown in FIG. 8, the partition plate 164 is arranged on the upstream side from the projecting portion 162. However, the partition plate 164 may be arranged on the downstream side from the projecting portion 162 as well.

The heat sink 150 of the second embodiment is provided with the partition plate 164 at the top edges of the fins 160, therefore the heat generated by the electronic module 44 is propagated, through the bottom surface 153 of the housing 152 and the fins 160, to the partition plate 164. For this reason, a heat dissipation area of the portion to which the heat generated by the electronic module 44 is propagated increases, so the cooling efficiency can be improved more than the first embodiment.

### (3) Third Embodiment

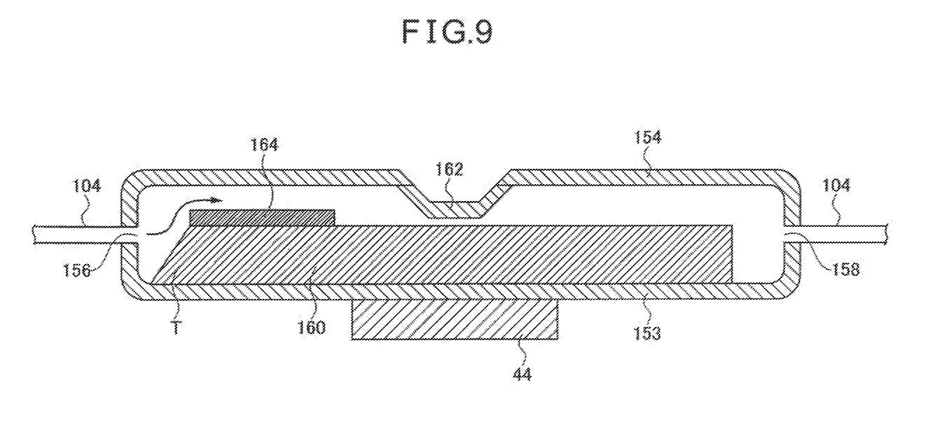

Next, a third embodiment according to the invention will be explained. The third embodiment is different in the configuration of the heat sink 150 from the second embodiment explained before. Below, the configuration of the heat sink 150 of the third embodiment will be explained with reference to FIG. 9. FIG. 9 is a cross-sectional view showing an example of the heat sink 150 of the third embodiment. As shown in FIG. 9, this differs from the second embodiment in the point that the shape of the upstream side edges (portions indicated by T in FIG. 9) of the fins 160 of the heat sink 150 of the third embodiment is a tapered shape. The rest of the configuration is similar to that of the second embodiment, so the explanation will be omitted.

As shown in FIG. 9, since the upstream side edges of the fins 160 of the third embodiment are a tapered shape, the coolant which flows into the internal portion of the housing 152 from the inflow port 156 can easily flow between the top edges of the fins 160 and the top surface 154 of the housing 152 along the tapered shapes. As a result, the flow velocity of the coolant which flows between the top edges of the fins 160 and the top surface 154 of the housing 152 becomes larger. Due to striking the projecting portion 162, on the downstream side from the projecting portion 162, the velocity of the coolant which flows among the fins 160 rises. In this way, in the heat sink 150 of the embodiment based on the present invention as well, the cooling efficiency can be improved.

Note that, in the example shown in FIG. 9, an explanation was given for the case where a partition plate 164 was disposed at the top edges of the fins 160. However, the third embodiment can be applied even in a case where there is no partition plate 164.

### (4) Fourth Embodiment

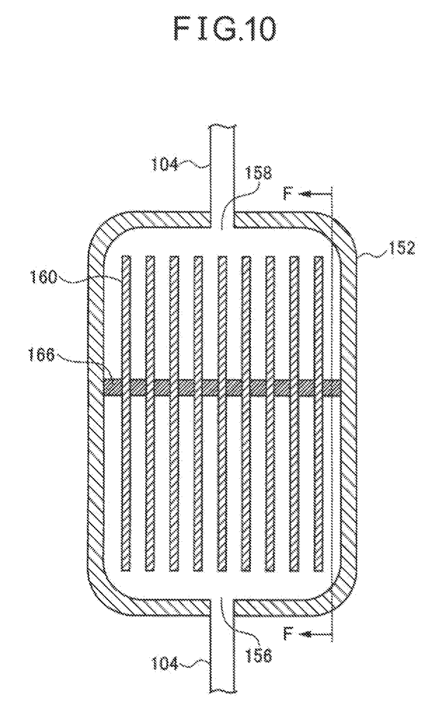

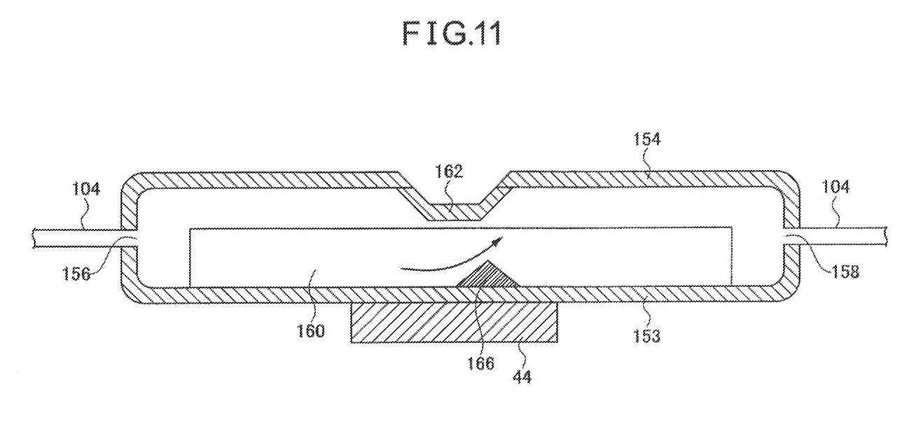

Next, a fourth embodiment according to the invention will be explained. The fourth embodiment differs from the first embodiment in the configuration of the heat sink 150. The rest of the configuration is similar to that of the first embodiment, therefore the explanation will be omitted. Below, the configuration of the heat sink 150 of the fourth embodiment will be explained with reference to FIG. 10 and FIG. 11. FIG. 10 is a plan view showing an example of the heat sink 150 when the top surface 154 of the housing 152 is removed. Further, FIG. 11 is a cross-sectional view as seen from an F-F arrow direction in FIG. 10.

As shown in FIG. 10 and FIG. 11, the heat sink 150 of the fourth embodiment differs from the first embodiment explained above in the point that a convex portion 166 is formed at the bottom surface of the housing 152. The rest of the configuration is similar to that of the first embodiment. As shown in FIG. 10, the convex portion 166 is formed among a plurality of fins 160. Further, as shown in FIG. 11, the convex portion 166 is preferably formed in the vicinity of the projecting portion 162 which is formed at the top surface 154 of the housing 152.

The convex portion 166 is formed together with the fins 160 at the bottom surface 153 of the housing 152 by for example die casting. Further, when the fins 160 are provided with concave portions which fit with the convex portion 166 formed at the bottom surface 153 of the housing 152, the convex portion 166 may be formed at the bottom surface 153 of the housing 152 by die casting, then the fins 160 attached to the convex portion 166.

Since the convex portion 166 is formed at the bottom surface 153 of the housing 152 of the heat sink 150 of the fourth embodiment, the coolant, which flows among the fins 160 on the upstream side from the convex portion 166 and rises in temperature, strikes the convex portion 166 so can easily flow to between the top edges of the fins 160 and the top surface 154 of the housing 152 on the downstream side from the convex portion 166. Further, the flow among the fins 160 can be disturbed and stirred. In this way, in the heat sink 150 of the fourth embodiment as well, the cooling efficiency can be improved.

### (5) Fifth Embodiment

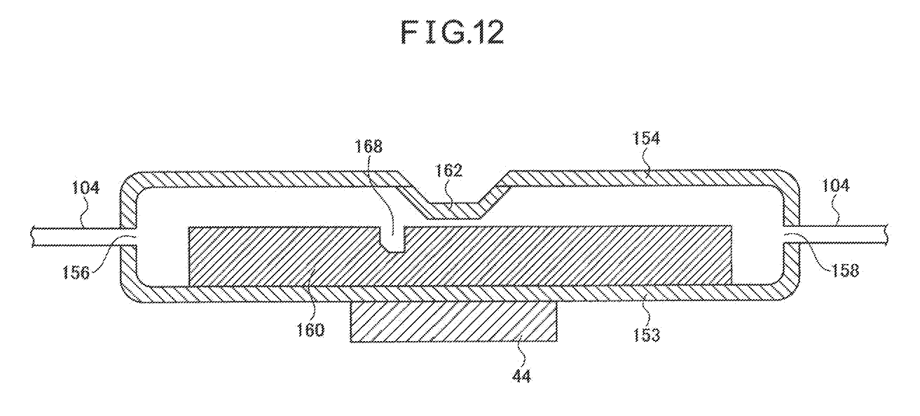

Next, a fifth embodiment according to the invention will be explained. The fifth embodiment differs from the first embodiment explained before in the configuration of the heat sink 150. The rest of the configuration is similar to that of the first embodiment, therefore the explanation will be omitted. Below, the configuration of the heat sink 150 of the fifth embodiment will be explained with reference to FIG. 12. FIG. 12 is a cross-sectional view showing an example of the structure of the internal portion of the heat sink 150 of the fifth embodiment.

As shown in FIG. 12, the heat sink 150 of the fifth embodiment differs from the first embodiment explained above in the point that recess portions 168 are formed at the top edges of the fins 160. The rest of the configuration is similar to that of the first embodiment. In the example shown in FIG. 12, the recess portions 168 are formed in the vicinity of the projecting portion 162. Note that, the number of the recess portions 168 formed in one fin 160 is not particularly limited. A plurality of recess portions 168 may be formed in one fin 160 as well. Further, the positions of formation of the recess portions 168 in the fins 160 may be different in each fin 160.

Since the recess portions 168 are formed in the fins 160 of the fifth embodiment, the coolant, which flows among the fins 160, passes through the recess portions 168 and easily flows to between adjacent fins 160. Further, in the fifth embodiment, since the recess portions 168 are formed in the top edges of the fins 160, the coolant which flows between the top edges of the fins 160 and the top surface 154 of the housing 152 easily passes through the recess portions 168 and flows into the spaces among the fins 160. In this way, in the heat sink 150 of the fifth embodiment as well, the cooling efficiency can be improved.

### Modifications

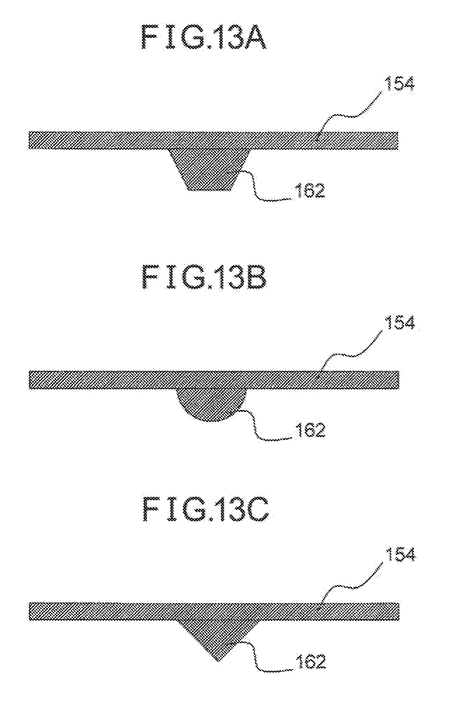

In the embodiments explained above, the example was given of forming the projecting portion 162 by pushing down a portion of the top surface 154 of the housing 152, but the shape of the projecting portion 162 is not limited to this. Here, with reference to FIGS. 13A to 13C, modifications of the projecting portion 162 will be explained. In FIGS. 13A, 13B, and 13C, the top surface 154 of the housing 152 and the projecting portion 162 are shown, but the other portions are omitted. As shown in FIGS. 13A, 13B, and 13C, the projecting portion 162 may be one added to the top surface 154 of the housing 152, as well.

Further, so far as the shape is such that the coolant, which flows between the top edges of the fins 160 and the top surface 154 of the housing 152, strikes the projecting portion 162 and easily flows into the spaces among the fins 160, the shape of the projecting portion 162 is not limited to the shape of the embodiments explained above. For example, the projecting portion 162 may be given a trapezoidal shape as shown in FIG. 13A, a semi-circular shape as shown in FIG. 13B, or a triangular shape as shown in FIG. 13C, as well.

A detailed explanation was given above on the heat sink, liquid cooling unit, and electronic apparatus of the present invention, but the present invention is not limited to the above-described embodiments. Further, the embodiments explained above may be suitably combined. Further, it should be understood by those skilled in the art that various modifications and alterations may occur depending on design requirements and other factors insofar as they are within the scope of the appended claims or the equivalents thereof.

All examples and conditional language recited herein are intended for pedagogical purposes to aid the reader in understanding the invention.

What is claimed is:

1. A heat sink for absorbing heat which is generated by an electronic module by using a coolant which flows in its internal portion, comprising
a housing provided with, in its internal portion, a first surface located in the vicinity of the electronic module and a second surface facing the first surface and
fins extending from the first surface toward the second surface, wherein
a projecting portion which is projected from the second surface toward the first surface and is formed at the second surface, between the top edges of the fins on the second surface side and the second surface.

2. The heat sink according to claim 1, wherein a partition plate parallel to the first surface is provided at the top edges of the fins on the second surface side.

3. The heat sink according to claim 1, wherein the shape of the upstream side edges of the fins is a tapered shape.

4. The heat sink according to claim 1, wherein a convex portion is formed at the first surface.

5. The heat sink according to claim 1, wherein recess portions are formed in the fins.

6. A liquid cooling unit comprising:
a heat sink absorbing heat which is generated by an electronic module by a coolant which flows in the internal portion;
a heat exchanger taking the heat from the coolant; and
a pump circulating the coolant, wherein
the heat sink comprising
a housing provided with, in its internal portion, a first surface located in the vicinity of the electronic module and a second surface facing the first surface and
fins extending from the first surface toward the second surface, and
a projecting portion which is projected from the second surface toward the first surface and is formed at the second surface, between the top edges of the fins on the first surface side and the second surface.

7. An electronic apparatus comprising:
an electronic module generating heat;
a heat sink absorbing the heat generated by the electronic module by using a coolant which flows in the internal portion;
a heat exchanger taking the heat from the coolant; and
a pump circulating the coolant, wherein
the heat sink comprising
a housing provided with, in its internal portion, a first surface located in the vicinity of the electronic module and a second surface facing the first surface and
fins extending from the first surface toward the second surface, and
a projecting portion which is projected from the second surface toward the first surface and is formed at the second surface, between the top edges of the fins on the second surface side and the second surface.
